(19) United States
(12) Patent Application Publication
(10) Pub. No.: US 2012/0006676 A1
(43) Pub. Date: Jan. 12, 2012

(54) POTASSIUM/MOLYBDENUM COMPOSITE METAL POWDERS, POWDER BLENDS, PRODUCTS THEREOF, AND METHODS FOR PRODUCING PHOTOVOLTAIC CELLS

(75) Inventors: David Honecker, Sahuarita, AZ (US); Michael Carducci, Sahuarita, AZ (US); Carl Cox, Sahuarita, AZ (US); Christopher Michaluk, Tucson, AZ (US)

(73) Assignee: Climax Engineered Materials, LLC, Phoenix, AZ (US)

(21) Appl. No.: 13/178,678

(22) Filed: Jul. 8, 2011

Related U.S. Application Data
(60) Provisional application No. 61/363,051, filed on Jul. 9, 2010.

(51) Int. Cl. H01B 1/02; B22F 3/12; B22F 3/15; B32B 15/00; C23C 14/34; B22F 9/04; B22F 1/00; B29B 9/12; C23C 14/14

(52) U.S. Cl. 204/192.15; 264/12; 419/38; 75/228; 204/298.12; 241/30; 428/548; 252/512

(57) ABSTRACT

A method for producing a composite metal powder according to one embodiment of the invention may comprise: Providing a supply of molybdenum metal powder; providing a supply of a potassium compound; combining the molybdenum metal powder and the potassium compound with a liquid to form a slurry; feeding the slurry into a stream of hot gas; and recovering the composite metal powder.

### CROSS-REFERENCE TO RELATED APPLICATION

This application claims the benefit of U.S. Provisional Patent Application No. 61/363,051, filed on Jul. 9, 2010, which is hereby incorporated herein by reference for all that it discloses.

### TECHNICAL FIELD

This invention relates molybdenum-containing materials and coatings in general and more specifically to molybdenum coatings suitable for use in the manufacture of photovoltaic cells.

### BACKGROUND

Molybdenum coatings are well-known in the art and may be applied by a variety of processes in a wide variety of applications. One application for molybdenum coatings is in the production of photovoltaic cells. More specifically, one type of high-efficiency polycrystalline thin film photovoltaic cell involves an absorber layer comprising CuInGaSe₂. Such photovoltaic cells are commonly referred to as “CIGS” photovoltaic cells after the elements comprising the absorber layer. In a common construction, the CuInGaSe₂ absorber layer is formed or “grown” on a soda-lime glass substrate having a molybdenum film deposited thereon. Interestingly, it has been discovered that small quantities of sodium from the soda-lime glass substrate diffusing through the molybdenum film serve to increase the efficiency of the cell. See, for example, K. Ramanathan et al., Photovolt. Res. Appl. 11 (2003), 225; John H. Scofield et al., Proc. of the 24^{th} IEEE Photovoltaic Specialists Conference, IEEE, New York, 1995, 164-167. While such efficiency gains are automatically realized in structures wherein the CIGS cell is deposited on soda-lime glass substrates, it has proven considerably more difficult to realize efficiency gains where other types of substrates are used.

For example, there is considerable interest in forming CIGS cells on flexible substrates so that the cells may be made lighter and may be readily conformed to a variety of shapes. While such cells have been made and are being used, the flexible substrates involved do not contain sodium. Consequently, the performance of CIGS cells manufactured on such substrates may be improved by doping the molybdenum layer with sodium. See, for example, Jae Ho Yun et al., Thin Solid Films, 515, 2007, 5876-5879.

### SUMMARY OF THE INVENTION

A method for producing a composite metal powder according to one embodiment of the invention may comprise: Providing a supply of molybdenum metal powder; providing a supply of a potassium compound; combining the molybdenum metal powder and the potassium compound with a liquid to form a slurry; feeding the slurry into a stream of hot gas; and recovering the composite metal powder. Also disclosed is a composite metal powder produced according to this process.

Another embodiment for producing a composite metal powder may comprise: Providing a supply of molybdenum metal powder; providing a supply of a potassium molybdate powder; combining the molybdenum metal powder and the potassium molybdate powder with water to form a slurry; feeding the slurry into a stream of hot gas; and recovering the composite metal powder. Also disclosed is a composite metal powder produced in accordance with this process.

Also disclosed is a method for producing a metal article that comprises: Producing a supply of a composite metal powder by: providing a supply of molybdenum metal powder; providing a supply of a potassium compound; combining the molybdenum metal powder and the potassium compound with a liquid to form a slurry; feeding the slurry into a stream of hot gas; and recovering the composite metal powder; and consolidating the composite metal powder to form the metal article, the metal article comprising a potassium/molybdenum metal matrix. Also disclosed is a metal article produced accordance with this method.

A method for producing a photovoltaic cell in accordance with the teachings provided herein may comprise: Providing a substrate; depositing a potassium/molybdenum metal layer on the substrate; depositing an absorber layer on the potassium/molybdenum metal layer; and depositing a junction partner layer on the absorber layer.

A method for depositing a potassium/molybdenum film on a substrate may comprise: Providing a supply of a composite metal powder comprising molybdenum and potassium; and depositing the composite metal powder on the substrate by thermal spraying. Another method for depositing a film on a substrate may comprise: Sputtering a target comprising a potassium/molybdenum metal matrix, sputtered material from the target forming the potassium/molybdenum film. Another method for coating a substrate may comprise: Providing a supply of composite metal powder comprising molybdenum and potassium; and evaporating the composite metal powder to form a potassium/molybdenum film. A method for coating a substrate may comprise: Providing a supply of a composite metal powder comprising molybdenum and potassium; mixing the supply of composite metal powder with a vehicle, and depositing the mixture of the composite metal powder and the vehicle on the substrate by printing.

A method for producing a metal article according to one embodiment may include: Providing a supply of a potassium/molybdenum composite metal powder; compacting the potassium/molybdenum composite metal powder under sufficient pressure to form a preformed article; placing the preformed article in a sealed container; raising the temperature of the sealed container to a temperature that is lower than a sintering temperature of molybdenum; and subjecting the sealed container to an isostatic pressure for a time sufficient to increase the density of the article to at least about 90% of theoretical density. Also disclosed is a metal article produced in accordance with this process.

Another method for producing a metal article may include: Providing a supply of a potassium/molybdenum composite metal powder; compacting the potassium/molybdenum composite metal powder under sufficient pressure to form a preformed article; placing the preformed article in a sealed container; raising the temperature of the sealed container to a temperature that is lower than the melting point of potassium molybdate; and subjecting the sealed container to an isostatic pressure for a time sufficient to increase the density of the article to at least about 95% of theoretical density.

### BRIEF DESCRIPTION OF THE DRAWINGS

Illustrative and presently preferred exemplary embodiments of the invention are shown in the drawings in which:

FIG. 1 is a schematic representation of one embodiment of basic process steps which may be utilized to produce a potassium/molybdenum composite metal powder;

FIG. 2 is a process flow chart depicting methods for processing the composite metal powder mixture;

FIG. 3 is an enlarged cross-sectional view in elevation of a photovoltaic cell having a potassium/molybdenum metal layer;

FIG. 4 is a scanning electron micrograph at 500× of a first sample portion of the potassium/molybdenum composite metal powder product;

FIG. 5a is a scanning electron micrograph of a second sample portion of the potassium/molybdenum composite metal powder product;

FIG. 5b is a spectral map produced by energy dispersive x-ray spectroscopy showing the dispersion of potassium in the image of FIG. 5a;

FIG. 5c is a spectral map produced by energy dispersive x-ray spectroscopy showing the dispersion of molybdenum of the image of FIG. 5a;

FIG. 6 is a schematic representation of one embodiment of pulse combustion spray dry apparatus;

FIG. 7 is an enlarged cross-sectional view in elevation of another embodiment of a photovoltaic cell having a potassium/molybdenum metal layer formed on a molybdenum metal layer;

FIG. 8a is an exploded perspective view of a container and preformed metal article;

FIG. 8b is a perspective view of a sealed container containing the preformed metal article;

FIG. 9 is a pictorial representation of a metal article that may be produced in accordance with the example process; and

FIG. 10 is a process flow chart of a method for producing a potassium/molybdenum dry blend powder.

### DETAILED DESCRIPTION OF THE PREFERRED EMBODIMENTS

U.S. Patent Application Publication No. 2009/0181179, entitled “Sodium/Molybdenum Composite Metal Powders, Products Thereof, and Methods for Producing Photovoltaic Cells,” which is specifically incorporated herein by reference for all that it discloses, describes our previous work with respect to sodium/molybdenum composite metal powders. More specifically, the patent application describes sodium/molybdenum composite metal powders, how to make the powders, and how the sodium/molybdenum composite metal powders may be used in the fabrication of CIGS devices to increase their efficiency. The addition of other Group IA alkali metals, such as potassium (K) and lithium (Li) should also result in similar efficiency gains in CIGS devices, as explained in U.S. Pat. No. 5,626,688 to Probst et al., entitled “Solar Cell with Chalcopyrite Absorber Layer.” The addition of a Group IA alkali metal also may be capable of passivating defects in the CIGS devices.

The present invention relates to Group IA alkali/molybdenum composite metal powders and powder blends, methods for making the composite metal powders and powder blends, and how composite metal powders and powder blends may be used in the fabrication of CIGS devices to increase their efficiencies. Prophetic and working examples involve the production of potassium/molybdenum composite metal powders and powder blends from various potassium compounds, including potassium molybdate. Prophetic and working examples involving the production of metal articles suitable for use as sputter targets are also provided. The sputter targets may be used to deposit potassium-doped molybdenum metal coatings in the fabrication of CIGS devices.

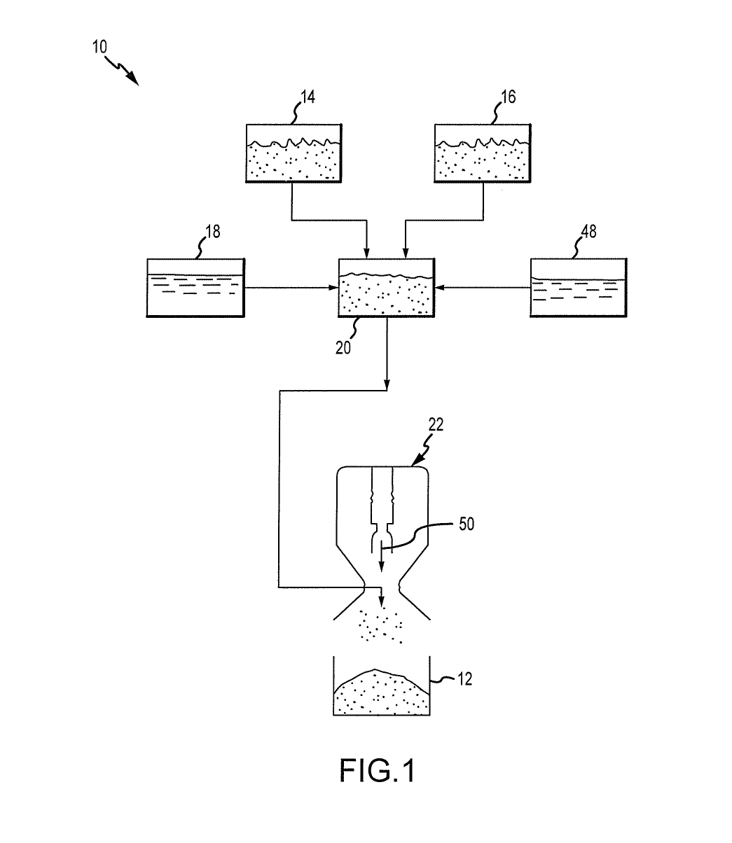

Referring now to FIG. 1, a spray dry process or method 10 for producing a potassium/molybdenum composite metal powder product 12 may comprise providing a supply of a molybdenum metal powder 14 and a supply of a potassium compound 16, such as, for example, potassium molybdate (K₂MoO₄) powder. The molybdenum metal powder 14 and potassium molybdate powder 16 are combined with a liquid 18, such as water, to form a slurry 20. The slurry 20 may then be spray dried, e.g., by a pulse combustion spray dryer 22, in order to produce the potassium/molybdenum composite metal powder 12.

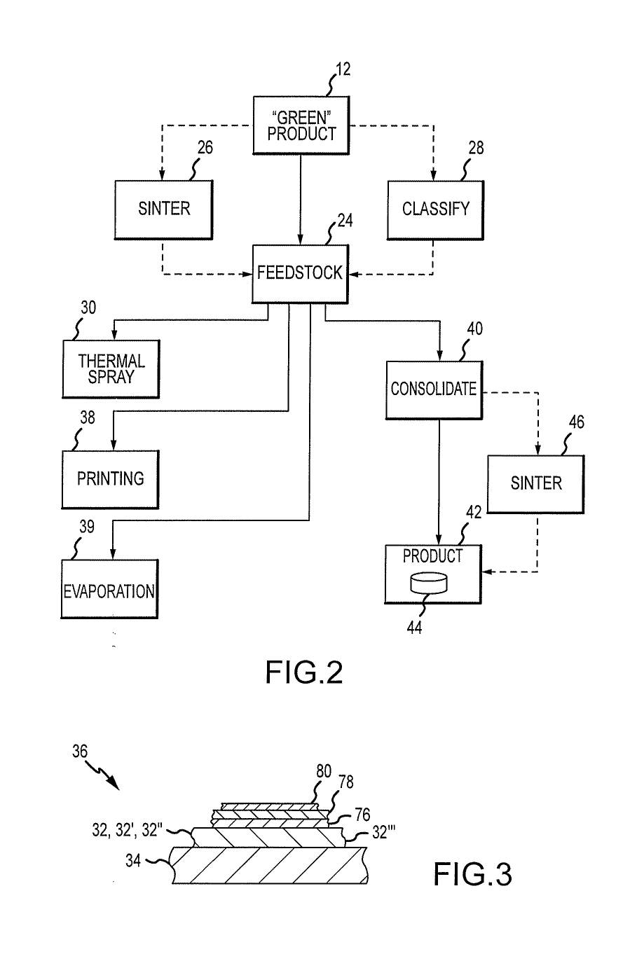

With reference primarily to FIG. 2, the potassium/molybdenum composite metal powder 12 produced by the spray dry process 10 may be used in its as-recovered or “green” form as a feedstock 24 for a variety of processes and applications, many of which are shown and described herein, and others of which will become apparent to persons having ordinary skill in the art after having become familiar with the teachings provided herein. Alternatively, the “green” composite metal powder 12 may be further processed, e.g., by sintering 26, by classification 28, or combinations thereof, before being used as feedstock 24.

The potassium/molybdenum composite metal powder feedstock 24 (e.g., in either the “green” form or in the processed form) may be used in a thermal spray deposition process in order to deposit a potassium/molybdenum film 32 on a substrate 34, as best seen in FIG. 3. Such potassium/molybdenum films 32 may be used to advantage in a wide variety of applications. For example, and as will be described in further detail below, the potassium/molybdenum film 32 may comprise a portion of a photovoltaic cell 36 and may be used to improve the efficiency of the photovoltaic cell 36. In an alternate deposition process, the composite metal powder 12 may also be used as a feedstock 24 in a printing process 38 which may also be used to form a printed potassium/molybdenum film or coating 32′ on substrate 34. In still another alternative, the composite metal powder 12 may be used as a feedstock 24 in an evaporation process 39 to deposit an evaporated potassium/molybdenum film or coating 32″

In still yet another embodiment, the composite metal powder feedstock 24, again in either its “green” form or in its processed form, may be consolidated at step 40 in order to produce a metal product 42, such as a sputter target 44. The metal product 42 may be used “as is” directly from consolidation 40. Alternatively, the consolidated product may be further processed, e.g., by sintering 46, in which case the metal product 42 will comprise a sintered metal product. In the case where the metal product 42 comprises a sputter target 44 (i.e., in either a sintered form or an un-sintered form), the sputter target 44 may be used in a sputter deposition apparatus (not shown) in order to deposit a sputtered potassium/molybdenum film 32″ on substrate 34. See FIG. 3.

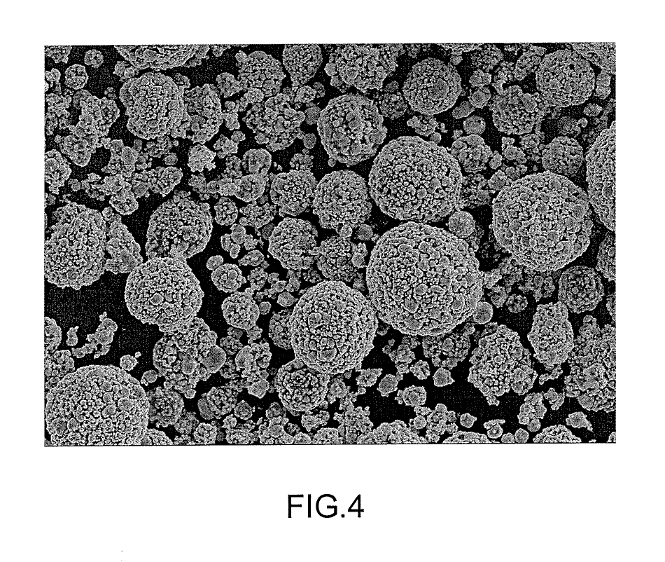

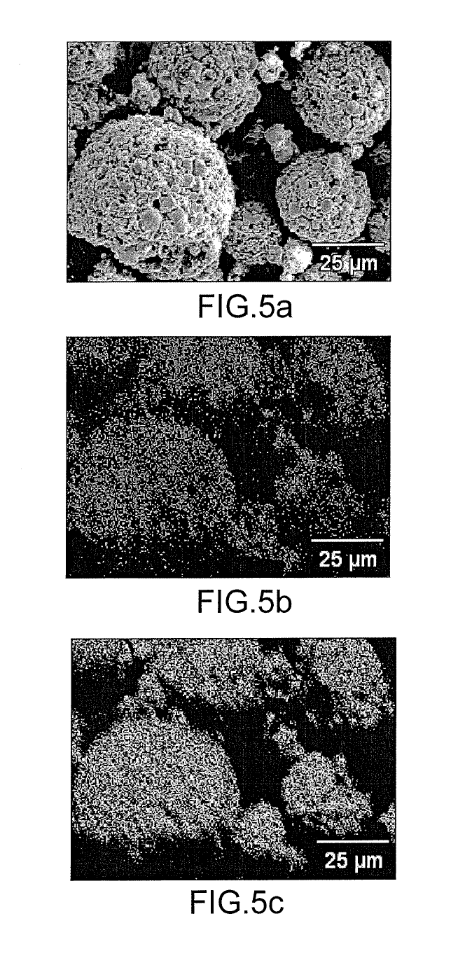

Referring now to FIGS. 4 and 5a-c, the potassium/molybdenum composite metal powder product 12 comprises a plurality of generally spherically-shaped particles that are themselves agglomerations of smaller particles. Moreover, and as evidenced by FIGS. 5a-c, the potassium is highly dispersed within the molybdenum. That is, the potassium/molybdenum composite powders of the present invention are not mere combinations of potassium metal powders and molybdenum metal powders, but rather comprise substantially homogeneous dispersions or composite mixtures of potassium and molybdenum sub-particles that are fused or agglomerated together.

The potassium/molybdenum metal composite powders 12 according to the teachings provided herein are also of high density, having Scott densities in a range of about 1.5 g/cc to about 3 g/cc. The potassium/molybdenum composite metal powders are also flowable after appropriate screening or classification.

A significant advantage of the present invention is that the potassium/molybdenum composite metal powder product 12 provides a combination of molybdenum and potassium that is otherwise difficult to achieve by conventional methods. Moreover, even though the potassium/molybdenum composite metal powder 12 comprises a powdered material, it is not a mere mixture of potassium and molybdenum particles. Instead, the composite powder 12 comprises sub-particles containing potassium and molybdenum that are actually fused together, so that individual particles of the powdered metal product 12 comprise both potassium and molybdenum. Accordingly, powdered feedstocks 24 comprising the potassium/molybdenum composite powders 12 according to the present invention should not separate (e.g., due to specific gravity differences) into potassium particles and molybdenum particles. Furthermore, metal articles (e.g., 42) formed from the composite metal powder 12, as well as coatings or films (e.g., 32, 32′, 32″, and 32′″) produced from the potassium/molybdenum composite metal powders 12 or metal articles 42 will have compositions that are similar to the compositions of the potassium/molybdenum metal powders 12 or articles 42 since such deposition processes do not rely on the co-deposition of separate molybdenum and potassium that would each have different deposition rates.

Besides the advantages associated with the ability to provide a composite metal powder product 12 wherein the potassium is highly and evenly dispersed throughout the molybdenum, potassium molybdate, unlike sodium molybdate, does not have a hydrated form. Consequently, pressed or compacted articles 42 formed from the potassium/molybdenum composite metal powders 12 described herein may be less prone to cracking and other structural problems that may arise over time compared to articles formed from sodium/molybdenum composite metal powders.

Still other advantages are associated with the comparatively high densities and flowabilities (i.e., after screening) of the potassium/molybdenum composite metal powders of the present invention. The high densities and flowabilities will allow the potassium molybdenum composite metal powders 12 to be readily used in a wide variety of thermal spray deposition apparatus and associated processes to deposit potassium/molybdenum films or coatings on various substrates. The powders 12 should also be usable in a wide variety of consolidation processes, such as cold and hot isostatic pressing processes, as well as pressing and sintering processes. The good flowability (i.e., after screening) should allow the powders disclosed herein to readily fill mold cavities, whereas the high densities should serve to minimize part shrinkage that may occur during subsequent sintering. Sintering can be accomplished by heating in an inert atmosphere or in hydrogen to further reduce oxygen content of the compact, if desired.

In another embodiment, the potassium/molybdenum composite metal powders 12 may be used to form sputter targets 44, which may then be used in subsequent sputter deposition processes to form potassium/molybdenum films and coatings. In one embodiment, such potassium/molybdenum films may used to increase the energy conversion efficiencies of CIGS-type photovoltaic cells.

Having briefly described the potassium/molybdenum composite metal powders 12 of the present invention, methods for producing them, and how they may be used to produce potassium/molybdenum coatings or films on substrates, various embodiments of the composite powders, as well as methods for producing and using the composite powders will now be described in detail.

Referring back now primarily to FIG. 1, a method 10 for producing potassium/molybdenum composite powders 12 may comprise providing a supply of molybdenum metal powder 14 and a supply of a Group IA alkali metal or metal compound 16. Examples of a Group IA alkali metal or metal compound 16 include potassium, potassium compounds, lithium, and lithium compounds. Other embodiments may involve a mixture of Group IA alkali metal compounds, such as sodium and/or sodium compounds, potassium and/or potassium compounds, lithium and/or lithium compounds.

The molybdenum metal power 14 may comprise a molybdenum metal powder having a particle size in a range of about 0.1 μm to about 15 μm, although molybdenum metal powders 14 having other sizes may also be used. Molybdenum metal powders suitable for use in the present invention are commercially available from Climax Molybdenum, a Freeport-McMoRan Company. Alternatively, molybdenum metal powders from other sources and produced by other processes may be used as well. For example, in another embodiment, the molybdenum metal powder 14 may comprise spray dried molybdenum metal powder. In still another embodiment, the molybdenum metal powder 14 may comprise a molybdenum metal powder having a high density combined with a low sintering temperature, such as any of those described in U.S. Pat. No. 7,625,421 of Khan et al., and entitled “Molybdenum Metal Powders,” which is specifically incorporated herein by reference for all that it discloses.

In examples where the Group IA alkali metal or metal compound 16 is to comprise potassium, potassium molybdate (K₂MoO₄) may be used. Alternatively, other forms of potassium may be used including, but not limited to, elemental potassium, potassium oxide (K₂O), and potassium hydroxide (KOH). Potassium molybdate (K₂MoO₄) may be provided in aqueous form and may be conveniently used to produce the slurries described herein. Alternatively, potassium molybdate in powder form may also be used as the potassium compound 16. If a powder form is used, the particle size of the potassium molybdate powder is not particularly critical in embodiments wherein water is used as the liquid 18, because potassium molybdate is soluble in water. Potassium molybdate powders suitable for use in the present invention are commercially available from AAA Molybdenum Products, Inc., of Broomfield, Colo., 80020 (US). Alternatively, potassium molybdate powders from other sources may be used as well.

In embodiments where the Group IA alkali metal or metal compound 16 is to comprise lithium, then lithium molybdate (Li₂MoO₄) may be used. Alternatively, other forms of lithium may be used, including, for example, lithium hydroxide (LiOH), lithium carbonate (Li, CO₃), and lithium oxide (Li₂O).

In embodiments comprising a mixture of Group IA alkali metal compounds, such as a combination of sodium and potassium, then a mixture of sodium molybdate (Na₂MoO₄) and potassium molybdate (K₂MoO₄) may be used. We believe that a composite metal powder made from a mixture of sodium molybdate and potassium molybdate will provide advantages associated with both sodium and potassium. For example, CIGS-type photovoltaic cells fabricated from sputter targets 44 made from sodium-potassium/molybdenum composite metal powders may display the efficiency gains typically associated with the presence of sodium, while the sputter targets 44 themselves may exhibit the benefits associated with the presence of potassium, as described herein.

The molybdenum metal powder 14 and Group IA alkali metal or metal compound 16 (e.g., potassium molybdate) may be mixed with a liquid 18 to form a slurry 20. Generally speaking, the liquid 18 may comprise deionized water, although other liquids, such as alcohols, volatile liquids, organic liquids, and various mixtures thereof, may also be used, as would become apparent to persons having ordinary skill in the art after having become familiar with the teachings provided herein. Consequently, the present invention should not be regarded as limited to the particular liquids 18 described herein. In addition to the liquid 18, a binder 48 may be used as well, although the addition of a binder 48 is not required.

Binders 48 suitable for use in the present invention include, but are not limited to, polyvinyl alcohol (PVA), any of a number of polyethylene glycols (e.g., sold under variations of the registered trademark Carbowax®), and mixtures thereof. The binder 48 may be mixed with the liquid 18 before adding the molybdenum metal powder 14 and the potassium molybdate 16. Alternatively, the binder 48 could be added to the slurry 20, i.e., after the molybdenum metal 14 and potassium molybdate 16 have been combined with liquid 18.

The slurry 20 may comprise from about 15% to about 25% by weight liquid (e.g., either liquid 18 alone, or liquid 18 combined with binder 48), with the balance comprising the molybdenum metal powder 14 and the Group IA metal or metal compound 16. The Group IA metal or metal compound 16 (e.g., potassium molybdate) may be added in amounts suitable to provide the composite metal powder 12 and/or final product with the desired amount of “retained” potassium. Because the amount of retained potassium will vary depending on a wide range of factors, the present invention should not be regarded as limited to the provision of the potassium compound 16 in any particular amounts.

Factors that may affect the amount of potassium compound 16 that is to be provided in slurry 20 include, but are not limited to, the particular product that is to be produced, the particular “downstream” processes that may be employed, e.g., depending on whether the potassium/molybdenum composite metal powder 12 is to be subsequently sintered, and on whether the desired quantity of retained potassium is to be in the powder feedstock (e.g., 24) or in a deposited film or coating (e.g., 32, 32′, 32″, 32″). By way of example, the mixture of molybdenum metal 14 and potassium molybdate 16 may comprise from about 1% by weight to about 31% by weight potassium molybdate 16. However, in certain applications, e.g., wherein the potassium/molybdenum composite metal powder 12 is to be subsequently compacted into a sputter target 44, it may be preferable to limit the amount potassium molybdate 16 in the slurry 20 to no more than about 10% by weight, and more preferably no more than about 9% by weight, in order to reduce the likelihood that cracks will form during the fabrication of the sputter target 44. Overall, then, slurry 20 may comprise from about 0% by weight (i.e., no binder) to about 2% by weight binder 48. The balance of slurry 20 may comprise molybdenum metal powder 14 (e.g., in amounts ranging from about 52% by weight to about 84% by weight) and potassium molybdate 16 (e.g., in amounts ranging from about 1% by weight to about 31% by weight).

In embodiments involving a combination of Group IA alkali metals, such as a slurry made with a combination of sodium molybdate and potassium molybdate, the combined total amount of molybdate compound (e.g., the sodium and potassium molybdate) should be about the same for slurries involving a single alkali compound. For example, in an embodiment wherein the slurry 20 sodium molybdate and potassium molybdate, sodium molybdate may be added in amounts of about 5% by weight. Likewise, potassium molybdate may be added in amounts of about 5% by weight. Alternatively, other proportions may be used, as would become apparent to persons having ordinary skill in the art after having become familiar with the teachings provided herein. Consequently, the present invention should not be regarded as limited to any particular proportions of sodium and potassium in the slurry 20 or the final spray dried composite powder product 12.

After being prepared, the slurry 20 may be spray dried by any of a wide range of processes that are now known in the art or that may be developed in the future in order to produce the composite metal powder product 12. Consequently, the present invention should not be regarded as limited to any particular drying process. However, in one embodiment, the slurry 20 may be spray dried in a pulse combustion spray dryer 22. The pulse combustion spray dryer 22 may be of the type shown and described in U.S. Pat. No. 7,470,307, of Larink, Jr., entitled “Metal Powders and Methods for Producing the Same,” which is specifically incorporated herein by reference for all that it discloses.

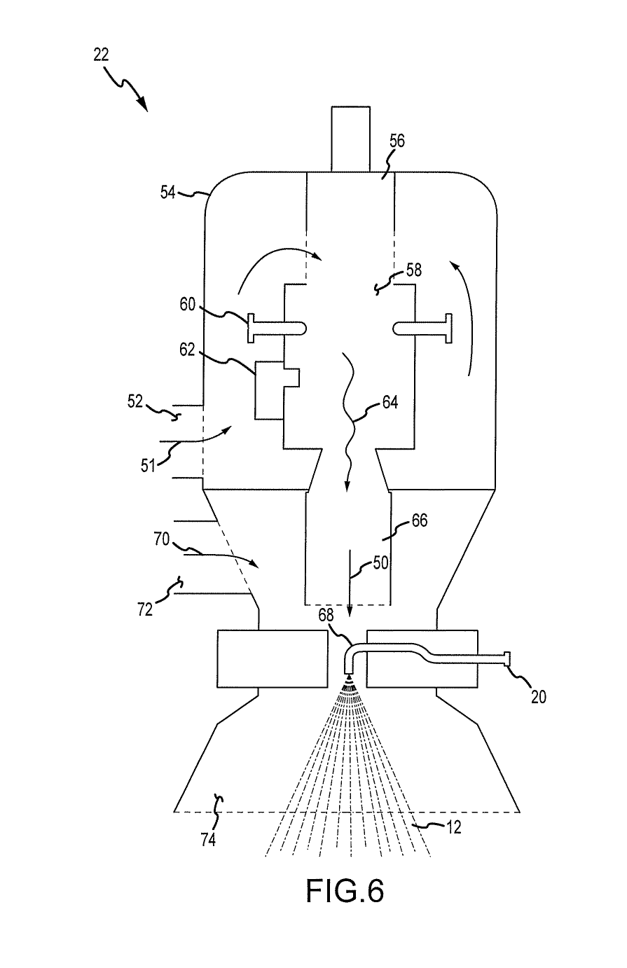

Referring now to FIGS. 1 and 6, slurry 20 may be fed into pulse combustion spray dryer 22, whereupon the slurry 20 impinges a stream of hot gas (or gases) 50 that is pulsed at or near sonic speeds. The sonic pulses of hot gas 50 contact the slurry 20 and drive off substantially all of the water and volatile components comprising slurry 20 to form the composite metal powder product 12. The temperature of the pulsating stream of hot gas 50 may be in a range of about 300° C. to about 800° C., such as about 465° C. to about 537° C., and more preferably about 500° C. The temperature of the pulsating stream of hot gas 50 is below the melting point of the molybdenum in the slurry 20, but may be close to, or even slightly higher than the melting point of the Group IA alkali metal or metal compound contained in the slurry 20. However, the slurry 20 is usually not in contact with the hot gases 50 long enough to transfer a significant amount of heat to the slurry 20, which is significant because of the low melting point of potassium and some potassium compounds. For example, in a typical embodiment, it is estimated that the slurry 20 is generally heated to a temperature in the range of about 93° C. to about 121° C. during contact with the pulsating stream of hot gas 50.

As mentioned above, the pulsating stream of hot gas 50 may be produced by a pulse combustion system 22 of the type that is well-known in the art and readily commercially available. The pulse combustion system 22 may comprise a pulse combustion system of the type shown and described in U.S. Pat. No. 7,470,307. Referring now to FIG. 6, combustion air 51 may be fed (e.g., pumped) at low pressure through an inlet 52 into the outer shell 54 of the pulse combustion system 22, whereupon it flows through a unidirectional air valve 56. The air then enters a tuned combustion chamber 58 where fuel is added via fuel valves or ports 60. The fuel-air mixture is then ignited by a pilot 62, creating a pulsating stream of hot combustion gases 64 which may be pressurized to a variety of pressures, e.g., in a range of about 15 kPa (about 2.2 psi) to about 20 kPa (about 3 psi) above the combustion fan pressure. The pulsating stream of hot combustion gases 64 rushes down tailpipe 66 toward the atomizer 68. Just above the atomizer 68, quench air 70 may be fed through an inlet 72 and may be blended with the hot combustion gases 64 in order to attain a pulsating stream of hot gases 50 having the desired temperature. The slurry 20 is introduced into the pulsating stream of hot gases 50 via the atomizer 68. The atomized slurry may then disperse in the conical outlet 74 and thereafter enter a conventional tall-form drying chamber (not shown). Further downstream, the composite metal powder product 12 may be recovered using standard collection equipment, such as cyclones and/or baghouses (also not shown).

In pulsed operation, the air valve 56 is cycled open and closed to alternately let air into the combustion chamber 58 and close for the combustion thereof. In such cycling, the air valve 56 may be reopened for a subsequent pulse just after the previous combustion episode. The reopening then allows a subsequent air charge (e.g., combustion air 51) to enter. The fuel valve 60 then re-admits fuel, and the mixture auto-ignites in the combustion chamber 58, as described above. This cycle of opening and closing the air valve 56 and combusting the fuel in the chamber 58 in a pulsing fashion may be controllable at various frequencies, e.g., from about 80 Hz to about 110 Hz, although other frequencies may also be used.

The “green” potassium/molybdenum composite metal powder product 12 that may be produced by the pulse combustion spray drying process described herein is illustrated in FIG. 4 and comprises a plurality of generally spherically-shaped particles that are themselves agglomerations of smaller particles. The potassium is highly dispersed within the molybdenum, so that the powder product 12 comprises a substantially homogeneous dispersion or composite mixture of potassium and molybdenum sub-particles that are fused together. See FIGS. 5a-c.

The composite metal powder product 12 that may be produced in accordance with the teachings provided herein comprises a wide range of particle sizes, and particles having sizes ranging from about 1 μm to about 150 μm, such as, for example, sizes ranging from about 5 μm to about 75 μm may be readily produced by the following the teachings provided herein. Of course, small fractions of particles having sizes outside these ranges may also be produced. The composite metal powder product 12 may be screened or classified e.g., at step 28 (FIG. 2), if desired, to provide a product 12 having a more narrow size range and increased flowability, if desired.

The potassium/molybdenum composite metal powder 12 is of a high density and should be quite flowable after appropriate screening/classification 28. For example, composite metal powder products 12 produced in accordance with the teachings provided herein may display Scott densities (i.e., apparent densities) in a range of about 1.5 g/cc to about 3 g/cc, with one particular powder example displaying a Scott density of about 2.7 g/cc, as reported in Table III.

In certain instances, residual amounts of liquid (e.g., liquid 18 and/or binder 48, if used) may remain in the resulting “green” composite metal powder product 12. If so, any remaining liquid 18 may be driven-off (e.g., partially or entirely), by a subsequent sintering or heating step 26. See FIG. 2. The heating or sintering process 26 should be conducted at a moderate temperatures in order to drive off the liquid components and oxygen. By way of example, heating 26 may be conducted at temperatures within a range of about 500° C. to about 1050° C., although higher temperatures are likely to reduce the amount of retained potassium in the final composite metal powder product 12. Some potassium may be lost during heating 26, which will reduce the amount of retained potassium in the sintered or feedstock product 24. Any expected loss of potassium resulting from heating 26 may be compensated by increasing the amount of potassium provided to slurry 20.

If such heating 26 is to be conducted, it will be generally preferred, but not required, to conduct such heating 26 in a hydrogen atmosphere in order to minimize oxidation of the composite metal powder 12. Retained oxygen should be low, less than about 9% for slurries comprising about 31% by weight potassium, with one particular powder example displaying a retained oxygen level of about 1.7% by weight, again as reported in Table III.

The agglomerations of the metal powder product are expected to retain their shapes (e.g., substantially spherical), even after the heating step 26. Thus, the flowability of the potassium/molybdenum composite metal powder 12 is expected to be unaffected by any such heating 26 that may be conducted.

As noted above, in some instances a variety of sizes of agglomerated products may be expected to be produced during the drying process, and it may be desirable to further separate or classify the composite metal powder product 12 into a metal powder product having a size range within a desired product size range. For example, in many embodiments, most of the composite metal powder material produced will comprise particle sizes in a wide range (e.g., from about 1 μm to about 150 μm), with a substantial amount of product being in the range of about 5 μm to about 75 μm (i.e., −200 US mesh).

A process hereof may yield a substantial percentage of product in this product size range; however, there may be remainder products, particularly the smaller products, outside the desired product size range which may be recycled through the system, though liquid 18 (e.g., water) would again have to be added to create an appropriate slurry composition. Such recycling is an optional alternative (or additional) step or steps.

The composite metal powder 12 may be used in its as-recovered or “green” form as a feedstock 24 for a variety of processes and applications, several of which are shown and described herein, and others of which will become apparent to persons having ordinary skill in the art after having become familiar with the teachings provided herein. Alternatively, the “green” composite metal powder product 12 may be further processed, such as, for example, by heating or sintering 26, by classification 28, and/or combinations thereof, as described above, before being used as feedstock 24.

The potassium/molybdenum composite metal powder 12 may be used in various apparatus and processes to deposit potassium/molybdenum films on substrates. In one application, such potassium/molybdenum films may be used to advantage in the fabrication of photovoltaic cells. For example, it is known that the energy conversion efficiency of a CIGS photovoltaic cell can be increased if sodium is allowed to diffuse into the molybdenum layer typically used to form an ohmic contact of the photovoltaic cell. In addition to sodium, other Group IA alkali metals, such as potassium and lithium, should result in similar efficiency gains.

Referring now to FIG. 3, a photovoltaic cell 36 may comprise a substrate 34 on which a potassium/molybdenum film 32, 32′, 32″, 32′″ may be deposited. The substrate 34 may comprise any of a wide range of substrates such as, for example, stainless steel, flexible poly films, or other substrate materials now known in the art or that may be developed in the future that are, or would be, suitable for such devices. A potassium/molybdenum film 32, 32′, 32″, 32′″ may then be deposited on the substrate 34 by any of a wide range of processes now known in the art or that may be developed in the future, but utilizing in some form the potassium/molybdenum composite metal powder material 12. For example, and as will be described in further detail below, the potassium/molybdenum film may be deposited by thermal spray deposition, by printing, by evaporation, or by sputtering.

After the potassium/molybdenum film (e.g., 32, 32′, 32″, 32′″) is deposited on substrate 34, an absorber layer 76 may be deposited on the potassium/molybdenum film. By way of example, the absorber layer 76 may comprise one or more selected from the group consisting of copper, indium, gallium, and selenium. The absorber layer 76 may be deposited by any of a wide range of methods known in the art or that may be developed in the future that are, or would be, suitable for the intended application. Consequently, the present invention should not be regarded as limited to any particular deposition process.

Next, a junction partner layer 78 may be deposited on the absorber layer 76. Junction partner layer 78 may comprise one or more selected from the group consisting of cadmium sulfide and zinc sulfide. Finally, a transparent conductive oxide layer 80 may be deposited on junction partner layer 78 to form the photovoltaic cell 36. Junction partner layer 78 and transparent conductive oxide layer 80 may be deposited by any of a wide range processes and methods now known in the art or that may be developed in the future that are, or would be, suitable for depositing these materials. Consequently, the present invention should not be regarded as limited to any particular deposition process.

In other embodiments, the potassium/molybdenum films (e.g., 32, 32′, 32″, 32′″) could be incorporated into CIGS photovoltaic cells having other structural configurations. For example, it is also known to construct CIGS photovoltaic devices in accordance with a superstrate configuration, in which the cell structure is inverted or reversed in comparison with a substrate configuration, an example of which was just described. Multi-junction configurations are also known and could also benefit from the teachings of the present invention. However, because various types of structures, configurations, and fabrication techniques for CIGS photovoltaic devices are known in the art (with the exception of providing the potassium/molybdenum film on a layer adjacent the active layer) and could be readily implemented by persons having ordinary skill in the art after having become familiar with the teachings of the present invention, the particular structure and fabrication techniques that may be utilized to construct a CIGS photovoltaic cell will not be described in further detail herein.

As mentioned above, the potassium/molybdenum layer or film 32, 32′, 32″, 32′″ may be deposited by any of a wide range of processes. It is believed that potassium concentrations ranging from about 1 atomic percent to about 15 atomic percent (about 1-3 atomic percent preferred) will be sufficient to provide the desired efficiency enhancements in most CIGS-type photovoltaic cells. Accordingly, the retained potassium present in the feedstock material 24 may be adjusted or varied as necessary in order to provide the desired level of potassium in the resulting potassium/molybdenum film 32. Generally speaking, it is believed that retained potassium levels ranging from about 0.3% by weight to about 11.3% by weight in the feedstock material 24 will be sufficient to provide the desired degree of potassium enrichment in the potassium/molybdenum film 32. Such retained potassium levels (e.g., from about 0.3 wt. % to about 11.3 wt. %) may be achieved in “green” and sintered (i.e., heated) feedstock material 24 produced by slurries 20 containing from about 3 wt. % to about 31 wt. % potassium molybdate.

In one embodiment, a potassium/molybdenum film 32 may be deposited by a thermal spray process 30 utilizing the feedstock material 24. Thermal spray process 30 may be accomplished by using any of a wide variety of thermal spray guns and operated in accordance with any of a wide range of parameters in order to deposit on substrate 34 a potassium/molybdenum film 32 having the desired thickness and properties. However, because thermal spray processes are well known in the art and because persons having ordinary skill in the art would be capable of utilizing such processes after having become familiar with the teachings provided herein, the particular thermal spray process 30 that may be utilized will not be described in further detail herein.

In another embodiment, a potassium/molybdenum film 32′ may be deposited on substrate 34 by a printing process 38 utilizing the feedstock material 24. Feedstock material 24 may be mixed with a suitable vehicle (not shown) to form an ink or paint that may then be deposited on substrate 34 by any of a wide range of printing processes. Here again, because such printing processes are well known in the art and could be readily implemented by persons having ordinary skill in the art after having become familiar with the teachings provided herein, the particular printing process 38 that may be utilized will not be described in further detail herein.

In still another embodiment, a potassium/molybdenum film 32″ may be deposited on substrate 34 by an evaporation process 39 utilizing the feedstock material 24. By way of example, in one embodiment, evaporation process 39 would involve placing the feedstock material 24 in a crucible (not shown) of a suitable evaporation apparatus (also not shown). The feedstock material 24 could be placed in the crucible either in the form of a loose powder, pressed pellets, or other consolidated forms, or in any combination thereof. The feedstock material 24 would the be heated in the crucible until it evaporates, whereupon the evaporated material would be deposited on substrate 34, forming the potassium/molybdenum film 32″.

Evaporation process 39 may utilize any of a wide range of evaporation apparatus now known in the art or that may be developed in the future that could be used to evaporate the feedstock material 24 and deposit film 32″ on substrate 34. Consequently, the present invention should not be regarded as limited to use with any particular evaporation apparatus operated in accordance with any particular parameters. Moreover, because such evaporation apparatus are well known in the art and could be readily implemented by persons having ordinary skill in the art after having become familiar with the teachings provided herein, the particular evaporation apparatus that may be utilized will not be described in further detail herein.

In yet another embodiment, a potassium/molybdenum film 32′″ may be deposited on substrate 34 by a sputter deposition process. The feedstock material 24 would be processed or formed into a sputter target 44, which would then be sputtered in order to form the film 32′″. Any of a wide range of sputter deposition apparatus that are now known in the art or that may be developed in the future could be used to sputter deposit film 32′″ on substrate 34. Consequently, the present invention should not be regarded as limited to use with any particular sputter deposition apparatus operated in accordance with any particular parameters. Moreover, because such sputter deposition apparatus are well known in the art and could be readily implemented by persons having ordinary skill in the art after having become familiar with the teachings provided herein, the particular sputter deposition apparatus that may be utilized will not be described in further detail herein.

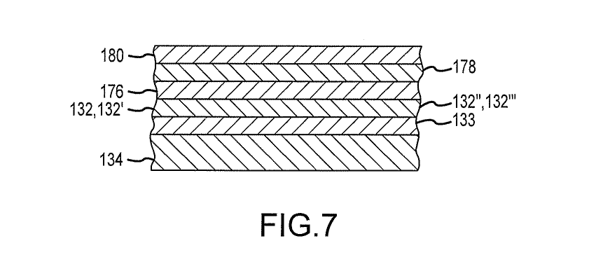

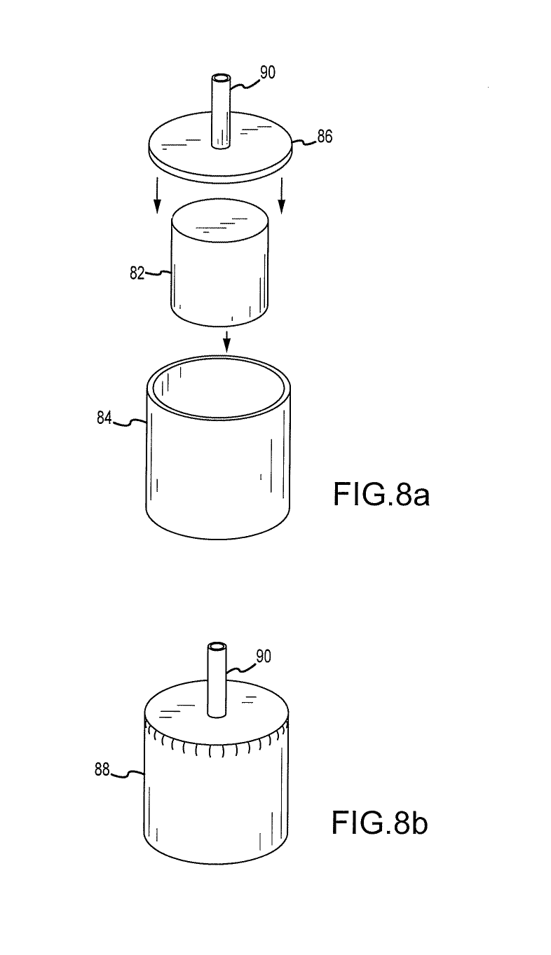

Still other variations and structures for incorporating potassium into the CIGS photovoltaic device are possible. For example, in another embodiment illustrated in FIG. 7, a potassium/molybdenum film (e.g., 132, 132′, 132″ or 132′″) could be provided, not directly on a substrate 134, but rather on a molybdenum metal layer 133 provided on substrate 134. That is, in a CIGS photovoltaic cell having a “substrate” type configuration, a substantially pure molybdenum metal back contact layer 133 may be provided directly on substrate 134. The potassium/molybdenum film (e.g., 132, 132′, 132″, or 132′″ deposited by the various techniques described herein) could then be deposited on the molybdenum metal back contact layer 133. An absorber layer 176 may be provided on the potassium/molybdenum film layer (e.g., 132, 132′, 132″, or 132′″), followed by a junction partner layer 178, and a transparent conductive oxide layer 180, in the manner already described. Such a structure would provide the desired amount of potassium to the absorber layer 176 while allowing a substantially pure molybdenum metal back contact layer 133 to be utilized.

In an embodiment wherein the potassium/molybdenum film 32′″, 132′″ is to be deposited by sputter deposition, the sputter target 44 may comprise a metal product 42 that may be fabricated by consolidating or forming the potassium/molybdenum composite metal powder 12 at step 40. Alternatively, the sputter target 44 could be formed by thermal spraying 30. If the sputter target 44 is to be fabricated by consolidation 40, the feedstock material 24, in either its “green” form or processed form, may be consolidated or formed in step 40 to produce the metal product (e.g., sputter target 44). The consolidation process 40 may comprise any of a wide range of compaction, pressing, and forming processes now known in the art or that may be developed in the future that would be suitable for the particular application. Consequently, the present invention should not be regarded as limited to any particular consolidation process.

The consolidation process 40 may comprise any of a wide range of cold isostatic pressing processes or any of a wide range of hot isostatic pressing processes that are well-known in the art. As is known, both cold and hot isostatic pressing processes generally involve the application of considerable pressure and heat (in the case of hot isostatic pressing) in order to consolidate or form the composite metal powder feedstock material 24 into the desired shape. Hot isostatic pressing processes may be conducted at temperatures of 890° C. or greater.

After consolidation 40, the resulting metal product 42 (e.g., sputter target 44) may be used “as is” or may be further processed. For example, the metal product 42 may be heated or sintered at step 46 in order to further increase the density of the metal product 42. It may be desirable to conduct such a heating process 46 in a hydrogen atmosphere in order to minimize the likelihood that the metal product 42 will become oxidized. Generally speaking, it will be preferred to conduct such heating at temperatures below about 1050° C., and more preferably below about 825° C., as higher temperatures may result in substantial reductions in the amount of retained potassium. The resulting metal product 42 may also be machined if necessary or desired before being placed in service. Such machining could be done regardless of whether the final product 42 was sintered.

As described above, the potassium/molybdenum composite metal powder 12 may be used to form or produce a variety of metal articles 42, such as a sputter target 44. The sputter target 44 may then be used to deposit a potassium-containing molybdenum film (e.g., film 32′″, 132′″) expected to be suitable for use in photovoltaic cells in the manner already described. Of course, the sputter targets 44 could be used to deposit potassium-containing molybdenum films for other applications as well.

U.S. Patent Application Publication No. 2009/0188789, entitled “Sodium/Molybdenum Powder Compacts and Methods for Producing the Same,” which is specifically incorporated herein by reference for all that it discloses, describes our previous work with respect to the consolidation of sodium/molybdenum composite metal powders to form metal articles, such as sputter targets. Similar techniques may be used to produce potassium/molybdenum powder compacts, such as sputter targets, suitable in the manufacture of CIGS devices.

More particularly, it will be desirable for any such sputter targets 44 have a high a density (e.g., at least about 90% of theoretical density), to reduce or eliminate the presence of interconnected porosity in the target, to maximize target life, and to minimize vacuum sputtering chamber pump-down time. Such sputter targets 44 may have a potassium content of about 3% by weight and an oxygen content of less than about 2.5% by weight. In many applications, sputter targets 44 having potassium levels of about 2.5% by weight and oxygen levels of less than about 2.2% by weight will provide good results in subsequent CIGS fabrication processes. Moreover, the sputter targets 44 should be substantially chemically homogeneous with respect to potassium, oxygen, and molybdenum. That is, the quantities of potassium, oxygen, and molybdenum should not vary by more than about 20% throughout a target 44. It would also be generally preferred that any such targets 44 be substantially physically homogeneous with respect to hardness. That is, the material hardness should not vary by more than about 20% over a given target 44.

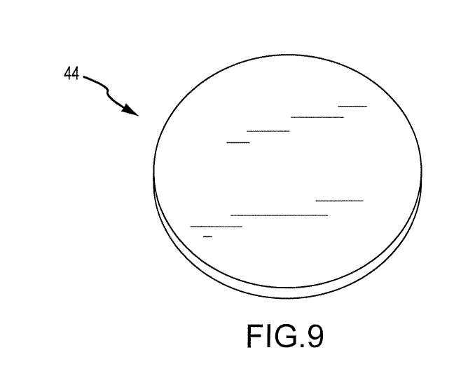

Referring now primarily to FIGS. 2, 8a, and 8b, a metal article 42 (FIG. 2), such as, for example, a sputter target 44 (FIGS. 2 and 9), may be produced by compacting a quantity of potassium/molybdenum composite metal powder 12 (i.e., as a feedstock material 24) under sufficient pressure to form a preformed metal article 82. See FIG. 8a. The preformed metal article 82 may then be placed in a container or form 84 suitable for use in a hot isostatic press (not shown). The form 84 may then be sealed, such as, for example, by welding a lid or cap 86 on the form 84 to create a sealed container 88. See FIG. 8b. The cap 86 may be provided with a fluid conduit or tube 90 to allow the sealed container 88 to be evacuated to degas the preformed metal article 82 in the manner that will be described in greater detail below.

The potassium/molybdenum composite metal powder 12 (i.e., as a feedstock 24) used to form the preformed metal article 82 may be used in its as-recovered or “green” form from the pulse combustion spray dryer 22 in the manner described above. Alternatively, and as already described above, the composite metal powder 12, may be further processed, such as, for example, by heating 26, by classification 28, and/or combinations thereof, before being used as the feedstock 24 for the preformed metal article 82.

In addition, and regardless of whether the powder 12 is heated (e.g., at step 26) or classified (e.g., at step 28), it should not be necessary, in most instances, to first dry the “green” potassium/molybdenum composite metal powder product 12 by subjecting it to a low-temperature heating step. However, depending on the particular circumstances, such low-temperature drying of the green potassium/molybdenum composite metal powder product 12 may be performed to remove any residual moisture and/or volatile compounds that may remain in the powder 12 after the spray drying process. Low-temperature drying of the powder may also provide the added benefit of increasing the flowability of the powder 12, which can be beneficial if the powder 12 is to be subsequently screened or classified. Of course, such a low-temperature drying process need not be performed if the powder 12 is to be heated in accordance with step 26 described above, because of the higher temperatures involved with heating step 26.

If it is desired to use a such a low-temperature drying process, then that process may involve heating the potassium/molybdenum composite metal powder 12 in a dry atmosphere, such as dry air, to a temperature in a range of about 100° C. to about 200° C. and for a time between about 2 hours and 24 hours.

After having provided the feedstock material 24 (e.g., in either its “green” form or dried form) of a suitable and/or desired particle size range, the potassium/molybdenum composite metal powder 12 comprising feedstock 24 may then be then compacted to form preformed article 82. If the metal article 42 to be produced is to comprise a sputter target 44, the preformed article 82 may comprise a generally cylindrically-shaped body, as best seen in FIG. 8a, although other shapes or configurations may be used.

After being fully consolidated in the manner described herein, the final metal article product 42 (i.e., the now-consolidated preformed cylinder) may then be cut into a plurality of disk-shaped sections or slices. The disk-shaped sections or slices may be subsequently machined to form one or more disk-shaped sputter targets 44. See FIGS. 2 and 9. Alternatively, of course, metal articles 42 having other shapes and configurations, and intended for other uses, could be produced in accordance with the teachings provided herein, as would become apparent to persons having ordinary skill in the art after having become familiar with the teachings provided herein. Consequently, the present invention should not be regarded as limited to metal articles having the particular shapes, configurations, and intended uses described herein.

In one embodiment, the preformed article 82 may be formed by a uniaxial compression process, wherein the feedstock material 24 (FIG. 2) is placed in a cylindrically-shaped die (not shown) and subjected to axial pressure in order to compress or compact the powdered feedstock material 24 so that it behaves as a nearly solid mass. Generally speaking, compaction pressures in a range of about 69 MPa (about 5 (short) tons per square inch (tsi)) to about 1,103 MPa (about 80 tsi) should provide sufficient compaction of the powdered feedstock material 24 so that the resulting preformed article 82 will be able to withstand subsequent handling and processing without disintegration.

In another embodiment, the preformed article 82 may be formed by a cold isostatic pressing process, wherein the feedstock material 24 (FIG. 2) is placed in a suitable mold or form (not shown) and subjected to “cold” isostatic pressure in order to compress or compact the powdered feedstock material 24 to form the preformed article 82. Isostatic pressures in a range of about 138 MPa (about 10 tsi) to about 414 MPa (about 30 tsi), should provide sufficient compaction.

After the preformed article 82 has been made (e.g., by uniaxial pressing, by cold isostatic pressing, or by some other compaction process), it may be sealed within the container 84, heated, and subjected to isostatic pressure in the manner described herein. Optionally, however, the “green” preformed article 82 may be further dried by heating the preformed article 82 before sealing it within container 84. If such a heating process is used, it will serve to drive off any moisture or volatile compounds that may be present in preformed article 82. Such heating could be conducted in a dry, inert atmosphere (e.g., argon), or simply in dry air. Alternatively, such heating could be conducted in a vacuum. If such an optional heating step is used, the preformed article 82 may be heated in dry air at a temperature in a range of about 100° C. to about 200° C. (about 110° C. preferred) for a time in a range of about 8 hours to about 24 hours (about 16 hours preferred). Alternatively, the preformed article 82 can be heated until it displays no additional loss of weight.

The next step in the process or method for producing a metal article 42 (e.g., sputter target 44) involves placing the preformed article 82 in a container or form 84 suitable for use in a hot isostatic press (not shown). See FIG. 8a. In one embodiment, the container 84 may comprise a generally hollow, cylindrically-shaped member that is sized to closely receive the substantially solid, cylindrically-shaped preformed article 82. Thereafter, form 84 can be sealed, for example, by welding a top or cap 86 thereto, in order to create a sealed container 88. See FIG. 8b. Cap 86 may be provided with a fluid conduit or tube 90 to allow the sealed container 88 to be evacuated.

The various components (e.g., 84, 86, and 90) comprising the sealed container 88 may comprise any of a wide range of materials suitable for the intended application. However, care should be exercised in selecting the particular material to avoid those materials that may introduce unwanted contaminants or impurities into the final metal article product (e.g., sputter target 44). In embodiments utilizing the potassium/molybdenum powders 12 described herein as feedstock 24, the container material may comprise mild (i.e., low-carbon) steel or stainless steel. In either case, it may be beneficial to line the interior portions of the form 84 and cap 86 with a barrier material to inhibit diffusion of impurities from the form 84 and cap 86, particularly if they are fabricated from low-carbon steel. A suitable barrier material may comprise molybdenum foil (not shown), although other materials could be used.

After the preformed metal article 82 has been placed within the container 88, it may optionally be degassed by connecting the tube 90 to a suitable vacuum pump (not shown) to evacuate the container 88 and remove any unwanted moisture or volatile compounds that may be contained within container 88 or metal article 82. The container 88 may be heated during the evacuation process to assist in the degassing procedure. While the amount of vacuum and temperature that may be applied during the degassing process is not particularly critical, in one embodiment, sealed container 88 may be evacuated to a pressure in a range of about 1 millitorr to about 1,000 millitorr (about 750 millitorr preferred). It is generally preferred that the temperature be below the oxidation temperature of molybdenum (e.g., about 395-400° C.). The temperature may be in a range of about 100° C. to about 400° C., with a temperature of about 250° C. being preferred. The vacuum and temperature may be applied for a time period in a range of about 1 hour to about 4 hours (about 2 hours preferred). Once the degassing process is complete, the tube 90 may be crimped or otherwise sealed in order to prevent contaminants from re-entering the sealed container 88.

The preformed metal article 82 provided within sealed container 88 may then be further heated while also subjecting the sealed container 88 to isostatic pressure. The container 88 should be heated to a temperature that is less than the optimal sintering temperature of the molybdenum powder component (such as, for example, a temperature less than about 1250° C.) while subjecting it to isostatic pressure for a time sufficient to increase the density of the preformed metal article 82 to at least about 90% of theoretical density. Isostatic pressures within a range of about 102 megapascals (MPa) (about 7.5 tsi) to about 205 MPa (about 15 tsi) and that are applied for a time period within a range of about 4 hours to about 8 hours typically will be sufficient to achieve density levels of at least about 90% of the theoretical density, and more preferably at least about 95% of the theoretical density.

After being heated and subjected to isostatic pressure, the final compacted article may be removed from the sealed container 88 and machined into final form. The compacted article may be machined in accordance with techniques and procedures generally applicable to the machining of molybdenum metal.

Potassium concentrations of the metal article sputter targets 44 of about 3% by weight or greater, as determined by combustion gas analysis, can be readily obtained. Also significantly (i.e., for sputter targets intended to produce potassium-containing molybdenum films for photovoltaic cell manufacture), iron levels should be less than about 50 ppm, even with potassium levels of about 3% by weight. Purity of the sputter targets 44 should be high, generally containing impurities at levels less then about 1000 ppm (excluding oxygen, molybdenum, and potassium).

The foregoing description relates to composite metal powders 12 produced by the pulse combustion spray dry process 10, as well as the use of the composite metal powders 12 as feedstocks 24 for a variety of deposition processes (e.g., thermal deposition 30, printing 38, and evaporation 39) and for the manufacture of metal articles 42. However, in certain applications it may be possible or even advantageous to utilize dry blended metal powders as the feedstocks for the various processes and metal articles described herein.

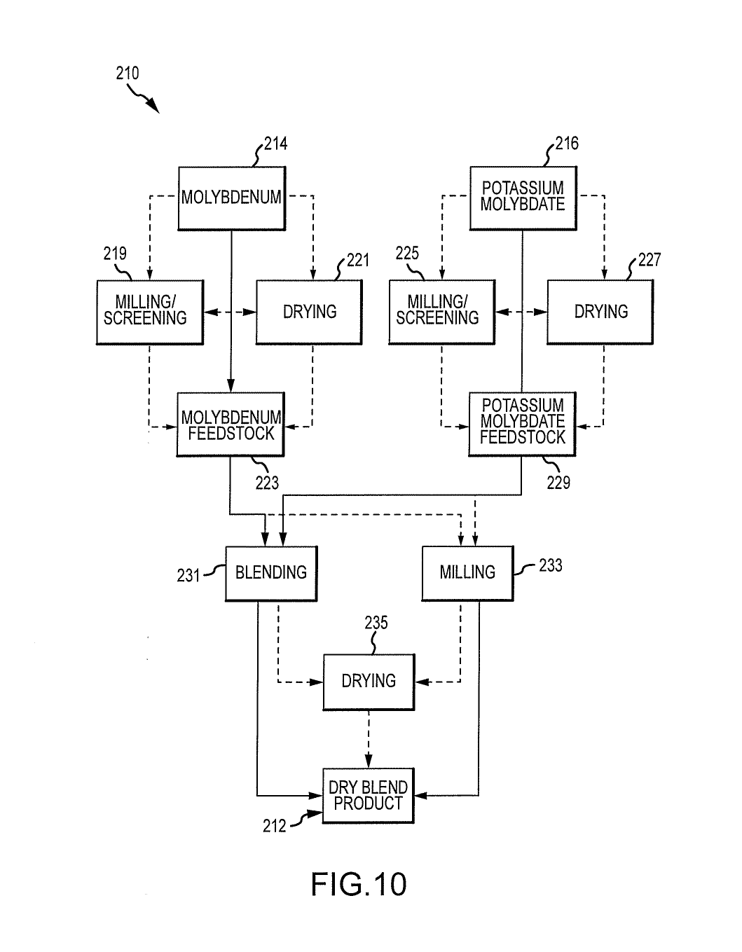

With reference now primarily to FIG. 10, a dry blend potassium/molybdenum powder product 212 may be produced by a dry blending process 210. As will be described in greater detail below, the dry blending process 210 may be used to provide the dry blend powder product 212 any desired amount of the Group IA alkali metal or metal compound (e.g., potassium molybdate), or combinations of alkali metal compounds (e.g., sodium molybdate and potassium molybdate) by simply varying the amount of the Group IA alkali metal or metal compound that is mixed with the molybdenum metal powder. Generally speaking, higher levels of the Group IA alkali metal (e.g., potassium molybdate, either alone or blended with sodium molybdate) can be provided in the final dry powder blend product 212 compared to a spray-dried product 12, because the process 210 is not limited to the maximum solubility of the Group IA metal or metal compound (e.g., potassium molybdate) in the liquid comprising the slurry. However, it should be noted that the resulting dry powder blend 212 will not be the same as the spray dried powder product 12. That is, while the spray dried powder product 12 comprises a substantially homogeneous dispersion or composite mixture of sub-particles comprising potassium and molybdenum that are fused or agglomerated together, the dry powder blend 212 will comprise a simple mixture or combination of molybdenum metal and potassium molybdate powders. Nevertheless, there may be applications and circumstances wherein the dry powder blend 212 could be used to advantage.

Dry blending process 210 may comprise providing a supply of a molybdenum metal powder 214 and a supply of a Group IA alkali metal or metal compound powder 216. However, instead of mixing the two powder supplies 214, 216 together to form a slurry, as was the case for the first embodiment 10 illustrated in FIG. 1, the two powder supplies 214, 216 are mixed or blended together in a dry form in order to produce the dry blend powder product 212.

More specifically, in the arrangement illustrated in FIG. 10, the supply of molybdenum metal powder 214 may comprise a “standard” molybdenum metal powder (i.e., produced by conventional techniques) of the type described above for the spray dry process 10. Alternatively, the molybdenum metal powder 214 may comprise a spray dried molybdenum metal powder. In still another embodiment, the molybdenum metal powder 214 may comprise a molybdenum metal powder having a high density combined with a low sintering temperature, such as any of those described in U.S. Pat. No. 7,625,421 of Khan et al and entitled “Molybdenum Metal Powders,” referenced above.

Depending on the particle size of the molybdenum metal powder supply 214, as well as on the desired particle size of the dry blend powder product 212, it may be necessary or desirable to mill and/or screen the molybdenum metal powder 214 at step 219 to produce a desirable particle size. Milling step 219 may comprise any of a wide range of milling apparatus and methods that are now known in the art or that may be developed in the future that are, or would be, suitable for the particular application and to achieve the desired particle size for the molybdenum metal powder 214. Exemplary milling processes include jet milling, ball milling, and attrition milling.

The molybdenum metal powder supply 214 may also be subjected to a drying step 221 in order to remove or drive off any moisture that may be present in the molybdenum metal powder supply 214. Generally speaking, drying step 221 should heat the molybdenum metal powder 214 to a temperature of at least about 100° C. to ensure that any moisture present (e.g., typically water) will be driven off. Drying step 221 may be conducted either before or after milling/screening step 219. Alternatively, drying 221 may be conducted even in the absence of a milling/screening step 219, although screening of the dried product may be performed if necessary to produce a feedstock 223 having the desired particle size.

Regardless of whether the molybdenum metal powder supply 214 was subjected to milling/screening 219, drying 221, or combinations thereof, the resulting molybdenum metal powder may be used as feedstock 223 for the blending and milling processes 231 and 233 described below that may be used to combine the two powders.

Method 210 also involves providing a supply of a Group IA alkali metal or metal compound 216. As explained above, examples of a Group IA alkali metal or metal compound 216 include potassium, potassium compounds, lithium, and lithium compounds. In the particular embodiment shown and described herein, the Group IA alkali metal or metal compound comprises potassium molybdate (K₂MoO₄). The Group IA alkali metal or metal compound (e.g., potassium molybdate) should be provided in powder form to facilitate the dry blending process.

Depending on the particle size of the potassium molybdate powder supply 216, as well as on the desired particle size of the dry blend powder product 212, it may be necessary or desirable to mill and/or screen the potassium molybdate 216 at step 225 to produce a desirable particle size. Milling 225 may comprise any of a wide range of milling apparatus and methods that are now known in the art or that may be developed in the future that are, or would be, suitable for the particular application and to achieve the desired particle size for the supply of potassium molybdate 216. Exemplary milling processes include jet milling, ball milling, and attrition milling.

The potassium molybdate 216 also may be subjected to a drying step 227 in order to remove or drive off any moisture that may be present in the potassium molybdate 216. Drying step 227 should be conducted so as to heat the potassium molybdate powder 216 to a temperature of at least about 100° C. to ensure that any moisture present (e.g., typically water) will be driven off. Drying step 227 may be conducted either before or after milling/screening step 225. Alternatively, drying 227 may be conducted even in the absence of a milling/screening step 225, although screening of the dried product may be performed if necessary to produce a feedstock 229 having the desired particle size.

Regardless of whether the supply of potassium molybdate 216 was subjected to milling/screening 225, drying 227, or combinations thereof, the resulting potassium molybdate powder may be used as a feedstock 229 for combination with the molybdenum metal powder feedstock 223. In one embodiment, the potassium molybdate powder feedstock 229 (i.e., unprocessed, milled and/or dried, as the case may be) may be combined with the molybdenum metal powder feedstock 223 by mixing or blending them together at step 231. Blending 231 may comprise any of a wide range of blending or mixing apparatus and methods that are now known in the art or that may be developed in the future that are, or would be, suitable for the particular materials involved. Exemplary blending apparatus include V-blenders and turbulizer blenders.

In another embodiment, the molybdenum metal powder feedstock 223 and the potassium molybdate powder feedstock 229 may be combined by milling at step 233. Milling 233 may comprise any of a wide range of media-based milling processes, including ball milling and jar milling. Milling 233 may be conducted until the powder feedstocks 223 and 229 have been thoroughly combined. Milling 233 may also be conducted until the combined powders have achieved a desired particle size.

Regardless of the particular process (e.g., blending 231 or milling 233) that is used to combine the powder feedstocks 223 and 229, the resulting combined powder may be subjected to a drying step 235 in order to remove or drive off any moisture that may be present in the powder blend. Drying step 235 may be conducted so as to heat the powder blend to a temperature of at least about 100° C. to ensure that any moisture present (e.g., water) will be removed.

The resulting dry powder blend 212 (i.e., undried or dried, as the case may be) may be conveniently provided with a desired amount of potassium by varying the amount of potassium molybdate powder feedstock 229 that is mixed with the molybdenum metal powder feedstock 223, i.e., during blending 231 or milling 233. Generally speaking, higher levels of the Group IA alkali metal (e.g., potassium) can be provided in the final dry powder blend product 212 compared to a spray-dried product 12, because the process 210 is not limited to the maximum solubility of the Group IA metal or metal compound (e.g., potassium molybdate) in the liquid comprising the slurry. However, it should be noted that the resulting dry powder blend 212 will not be the same as the spray dried powder product 12. That is, while the dry powder blend 212 will comprise a simple mixture or combination of molybdenum metal and potassium molybdate powders, the spray dried powder product 12 will comprise a substantially homogeneous dispersion or composite mixture of potassium and molybdenum sub-particles that are fused or agglomerated together. Nevertheless, there may be applications and circumstances wherein the dry powder blend 212 could be used to advantage.

In addition to embodiments comprising molybdenum and a single Group IA alkali metal or metal compound, other embodiments of the invention may comprise molybdenum and two or more Group IA alkali metals or metal compounds. For example, another embodiment may involve powders comprising molybdenum, potassium, and sodium. Moreover, such powders may be fabricated in accordance with the spray dry process 10 or the dry blend process 210 described herein to form either a spray dried powder product or a dry blend powder product. The resulting powder products (e.g., containing molybdenum and two or more Group IA alkali metals or metal compounds) may be useful for any of a wide range of applications. For example, such powder products containing two or more Group IA alkali metals or metal compounds may be used to enhance the efficiencies of CIGS-type photovoltaic cells in the manner described herein for powder products comprising sodium/molybdenum, potassium/molybdenum, and lithium/molybdenum.

The two or more Group IA alkali metals or metal compounds may be provided in any of the forms specified herein for the other embodiments before being spray dried (e.g., according to process 10) or dry blended (e.g., according to process 210). In one example embodiment, the particular Group IA alkali metals may be provided as molybdates of those metals. For example, potassium may be provided as potassium molybdate and sodium may be provided as sodium molybdate.

For any particular powder product containing a desired amount of the two or more Group IA alkali metals or metal compounds, the relative proportions of the constituents that should be provided as precursors (e.g., as feedstocks for the slurry or for the blend) may be different depending on whether the powder product is to comprise the spray dried powder product or the dry blend powder product, because they involve different physical phases. For example, higher proportions of the Group IA alkali metals will need to be added if the resulting powder product is to be produced by the spray dried process 10 than if the powder product is to be produced by the dry blend process 210.

### Prophetic Examples Powders

Several powder lots may be produced in accordance with the spray dry process 10 illustrated in FIG. 1. The spray dried powder lots may be produced using respective supplies of molybdenum metal powder 14 and potassium molybdate 16, as specified herein. Various ratios of the molybdenum powder and potassium molybdate may be combined to form various slurries 20. Additional amounts of deionized water may be added, if required, in order to achieve the relative weight percentages of the various slurry constituents in accordance with the values specified herein. More specifically, example slurries 20 may be prepared that comprise about 20% by weight water (i.e., liquid 18), with the remainder being molybdenum metal powder and potassium molybdate. The ratio of molybdenum metal powder to potassium molybdate may be varied to range from about 1% by weight to about 31% by weight potassium molybdate. More specifically, prophetic examples may involve amounts of 3, 7, 15, and 31 weight percent potassium molybdate.

The slurries 20 may then be fed into the pulse combustion spray drying system 22 in the manner described herein. The temperature of the pulsating stream of hot gases 50 may be controlled to be within a range of about 465° C. to about 537° C. The pulsating stream of hot gases 50 produced by the pulse combustion system 22 will substantially drive off the water from the slurry 20 to form the composite metal powder product 12. The contact zone and contact time should be very short. The contact zone may have a length on the order of about 5.1 cm and the time of contact may be on the order of 0.2 microseconds. The resulting metal powder product 12 should comprise agglomerations of smaller particles that are substantially solid and having generally spherical shapes.

Several dry blended powder lots may be produced by performing certain of the steps of the dry blend process 210 illustrated in FIG. 10. More specifically, a first powder lot may be produced by using a “standard” molybdenum metal powder supply 214 and a potassium molybdate powder supply 216. The supply of molybdenum metal powder 214 may be milled 219 and dried 221 in the manner described above to form a milled and dried molybdenum metal powder feedstock 223. The potassium molybdate powder supply 216 likewise may be milled 225 and dried 227 to produce a milled and dried potassium molybdate powder feedstock 229. The two powder feedstocks 223 and 229 may then be combined by mixing or blending at step 231. The combined powder may then be dried 235 in order to produce the first dry blend powder product lot 212.

A second dry blended powder product lot also may be produced. The second dry blend powder lot may be produced by following the process described above for the first dry blended powder lot, except that instead of combining the two powder feedstocks 223 and 229 by blending 231, the two powder feedstocks 223 and 229 are combined by milling 233. The combined powder may then be dried 235 in order to produce the second dry blend powder product lot 212.

A third dry blended powder product lot may be produced by using a “standard” molybdenum metal powder supply 214 and a potassium molybdate powder supply 216. The supply of molybdenum metal powder 214 may be dried 221 to in order to form a dried molybdenum metal powder feedstock 223. The potassium molybdate powder supply 216 may be milled 225 and dried 227 to produce a milled and dried potassium molybdate powder feedstock 229. The two powder feedstocks 223 and 229 may then be combined by mixing or blending at step 231 in order to produce the third dry blend powder product lot 212.

A fourth dry blend powder product lot may be produced by using a high-density, low-sintering temperature molybdenum metal powder, such as any of those described in U.S. Pat. No. 7,625,421 of Khan et al referenced above. The high-density, low-sintering temperature molybdenum metal powder 214 may be milled 219 and dried 221 to in order to form a milled and dried molybdenum metal powder feedstock 223. The potassium molybdate powder supply 216 may likewise be milled 225 and dried 227 in the manner already described to produce a milled and dried potassium molybdate powder feedstock 229. The two powder feedstocks 223 and 229 may then be combined by mixing or blending 231 in order to produce the fourth dry blend powder product lot 212.

### Prophetic Examples

### Metal Articles

A plurality of metal articles 42 (e.g., as sputter targets 44) may be produced or made from the potassium/molybdenum composite metal powders 12 produced by the spray dry process 10 illustrated in FIG. 1. Alternatively, metal articles 42 may be produced or made from the dry blend powder product 212 produced the dry blend process 210 illustrated in FIG. 10. The particular process used to form the metal articles 42 may be the same regardless of whether the powder feedstock used comprises the potassium/molybdenum composite metal powder 12 or the dry blend powder product 212.

A preformed metal article 82 used in process A may be formed from a “green” potassium/molybdenum composite metal powder 12 screened so that the particle size is less than about 105 μm (−150 Tyler mesh). A second preformed metal article 82 may be made with a potassium/molybdenum dry blend powder product 212 that has been dried and screened to result in a particle mixture having particles in a size range of about 53 μm to about 300 μm (−50+270 Tyler mesh).

The potassium/molybdenum composite metal powder 12 and the dry blend powder 212 that may be used to fabricate the preformed metal articles 82 may be cold pressed under a uniaxial pressure in a range of about 225 MPa (about 16.5 tsi) to about 275 MPa (about 20 tsi) to yield preformed cylinders (e.g., preformed metal articles 82). The preformed metal articles 82 may be placed in sealed containers 84 fabricated from a wide range of materials, stainless steel, low carbon steel lined with molybdenum foil, and plain (i.e., unlined) carbon steel.

Before being placed into the various containers 84 (e.g., fabricated from stainless steel or low-carbon steel and lined or un-lined with molybdenum foil), the preformed cylinders 82 may be heated to a temperature of about 110° C. in a dry air atmosphere for a period of about 16 hours in order to remove residual amounts of moisture and/or volatile components that may have been contained in the preformed cylinders 82. The dried cylinders 82 then may be placed in their respective containers and sealed in the manner described herein. The sealed containers 88 then may be degassed in the manner described herein by heating the sealed containers to a temperature of about 400° C. while subjecting them to a dynamic vacuum (about 750 millitorr). The degassed, sealed containers 88 may then be subjected to a isostatic pressure of about 205 MPa (i.e., 14.875 tsi) for a time of about 4 hours and at a temperature of about 890° C.

The resulting compacted metal cylinders then may be removed from the sealed containers 88, cut into disks, which may then be subsequently machined to form the final sputter targets 44. A representative machined disk (i.e., sputter target 44) that might be produced from the potassium/molybdenum composite metal powder product 12 is depicted in FIG. 9.

Still other variations are possible for producing metal articles with the potassium/molybdenum composite metal powders 12 and/or the dry blend metal powders 212 described herein. For example, in another embodiment, a closed die can be filled with a supply of potassium/molybdenum powder (e.g., either the composite metal powder 12 or the dry blend metal powder 212). The powder may then be axially compressed at a temperature and pressure sufficient to increase the density of the resulting metal article to at least about 90% of theoretical density. Still yet another variation may involve providing a supply of the potassium/molybdenum powder (e.g., either the composite metal powder 12 or the dry blend metal powder 212) and compacting the powder to form a preformed metal article. The article may then be placed in a sealed container and heated to a temperature that is lower than the melting point of potassium molybdate. The sealed container may then be extruded at a reduction ratio sufficient to increase the density of the article to at least about 90% of theoretical density.

### Working Examples

### Powders

An example slurry 20 was prepared in accordance with the teachings provided herein. The slurry 20 was then spray dried (e.g., by process 10) to produce an exemplary composite metal powder product 12. A scanning electron micrograph (SEM) of a first sample portion of the example composite metal powder product 12 is shown in FIG. 4. A scanning electron micrograph of a second sample portion of the example composite metal powder product 12 is shown in FIG. 5a. A corresponding spectral map produced by energy dispersive x-ray spectroscopy (EDS) showing the dispersion of potassium in the second sample portion is shown in FIG. 5b, whereas an EDS spectral map showing the dispersion of molybdenum is shown in FIG. 5c. The exemplary composite metal powder product 12 was then analyzed, the results of which are presented in Tables II-IV.

In particular, the slurry composition 20 was prepared by first combining about 10 kg (22 lbs) of liquid 18 with about 3.6 kg (about 8 lbs) potassium molybdate 16. In this particular example, the liquid 18 comprised deionized water, whereas the potassium molybdate 16 comprised a potassium molybdate powder from AAA Molybdenum Products, Inc., as specified herein. The deionized water 18 and potassium molybdate powder 16 were mixed together or blended for a time period of about 60 minutes to ensure full dissolution of the potassium molybdate powder 16 in the deionized water 18. Thereafter, about 45 kg (100 lbs) of molybdenum metal powder 14 was added to form the slurry 20. The molybdenum metal powder comprised molybdenum metal powder available from Climax Molybdenum Company as product “FM1.” The FM1 molybdenum metal powder is a highly pure (i.e., 99.95% minimum) molybdenum metal powder having a bulk density specification of 1.8-3.1 g/cc, a tap density specification greater than about 3.5 g/cc, and a particle size distribution specification of −325 US mesh. The resulting slurry 20 was blended or mixed together for a 60 minutes in order to ensure a well-mixed (i.e., substantially homogeneous) slurry 20.

The slurry 20 was then fed into the pulse combustion spray dryer 22 in the manner described herein to produce the composite metal powder product 12. The spray dryer 22 was operated to provide a heat release of about 84,400 kJ/hr (about 80,000 btu/hr), an exhaust air set point of approximately 70%, and a nozzle air pressure of about 110 kPa (about 16 psi). The feed rate of the slurry 20 was controlled to maintain a material exit temperature of about 116° C. (about 240° F.) Other operational parameters of the spray dryer 22 are provided in Table I.

TABLE I
SPRAY DRYER OPERATIONAL PARAMETERS

| Heat Release, kJ/hr (btu/hr) | 84,404 | (80,000) |
|---|---|---|
| Fuel Valve, (%) | 34.5 | |
| Contact Temp., ° C. (° F.) | 588 | (1,090) |
| Exit Temp., ° C. (° F.) | 116 | (240) |
| Outside Temp., ° C. (° F.) | 8.9 | (48) |
| Baghouse ΔP, mm H₂O (inches H₂O) | 6.8 | (0.27) |
| Turbo Air, kPa (psi) | 110 | (15.7) |
| RAV, (%) | 94.2 | |
| Ex. Air Setpoint, (%) | 70 | |
| Comb. Air Setpoint, (%) | 58 | |
| Quench Air Setpoint, (%) | 48 | |
| Trans. Air Setpoint, (%) | 5 | |
| Feed Pump, (%) | 7.2 | |
| Comb. Air Pressure, kPa (psi) | 10.2 | (1.48) |
| Quench Air Pressure, kPa (psi) | 9.17 | (1.33) |
| Combustor Can Pressure, kPa (psi) | 13.2 | (1.91) |

The resulting composite metal powder product 12 comprised generally spherically-shaped particles that are themselves agglomerations of small sub-particles, as best seen in FIG. 4. In some instances, the smaller sub-particles are also generally spherically-shaped, so that the agglomerated particles comprising the composite metal powder product 12 may be characterized in the alternative as “balls formed of spheres.”

Sieve analysis of the “as-produced” composite metal powder product 12 are provided in Table II. The sieve analysis indicates that the composite metal powder product 12 comprised particles ranging from about 74 μm to about 37 μm (e.g., about 33 wt. %), with a substantial number of particles (e.g., about 67 wt. %) having sizes smaller than 37 μm.

TABLE II
Sieve Analysis (US Mesh, wt. %)

| +60 | +100 | +140 | +200 | +270 | +325 | +400 | −400 |
|---|---|---|---|---|---|---|---|
| 0.0 | 0.0 | 0.0 | 0.6 | 9.7 | 9.8 | 12.5 | 67.4 |

Additional physical characteristics and powder assay results are presented in Tables III and IV. More specifically, Table III reports Scott density and Tap density. Theoretical density is also provided for comparison purposes. Table III also reports retained oxygen (in weight percent). Nitrogen, carbon, and sulfur contents are also reported on a parts per million (“ppm”) basis.

TABLE III

| Theoretical | Scott | Tap | | | | |
|---|---|---|---|---|---|---|
| Density | Density | Density | Oxygen | Nitrogen | Carbon | Sulfur |
| (g/cc) | (g/cc) | (g/cc) | (wt. %) | (ppm) | (ppm) | (ppm) |
| 8.99 | 2.71 | 3.82 | 1.65 | 29 | 47 | 3 |

Table IV reports retained potassium levels (in both weight percent and atomic percent), as determined by inductively coupled plasma mass spectroscopy (ICP). Trace amounts of iron, nickel, chromium, and tungsten are also provided on a ppm basis, as determined by glow discharge mass spectroscopy (GDMS).

TABLE IV

| Major Elements | | | | | | |
|---|---|---|---|---|---|---|
| (ICP) | | Trace Elements (GDMS), (ppm) | | | | |
| K (wt. %) | K (at. %) | Fe | Ni | Cr | W | Mo(wt. %) |
| 2.04 | 4.5 | 26 | 5 | 12 | 240 | 93.3 |

### Working Examples

### Metal Articles

A plurality of metal articles 42 (e.g., as sputter targets 44) were produced with the potassium/molybdenum composite metal powder 12 of the working example. Briefly, the metal articles 42 were produced by compacting the composite metal powder 12 by a cold isostatic pressing (“CIP”) process to form a preformed metal article 82. The preformed metal article 82 was then subjected to a hot isostatic pressing (“HIP”) process to form the final metal article or billet 42. The metal article or billet 42 was then machined to form a plurality of disk- or puck-shaped sputter targets 44. Data relating to the sputter targets 44 are provided in Tables VI-VIII.

In particular, the “green” composite metal powder 12 was compacted or consolidated by cold isostatic pressing to form a preformed metal article 82 having a generally cylindrical shape or configuration, as best seen in FIG. 8a. The preformed metal article 82 was then wrapped in molybdenum foil and placed in a container or can 84 comprised of low-carbon steel and capped in the manner described herein. After being placed within the container 88, the preformed cylindrical compact 82 was degassed by heating it under a vacuum of about 800 millitorr. The degassed container was then sealed (e.g., by crimping the fluid conduit 90) and subjected to the temperature and isostatic pressure schedule set forth in Table V.

In Table V, an upward-pointing arrow (i.e., “↑”) indicates that the pressure was increased to the stated pressure during the particular operation. Similarly, a downward-pointing arrow (i.e., “↓”) indicates that the pressure was reduced to the stated pressure during the particular operation. The absence of an arrow indicates that the pressure was held substantially constant during the operation. During the cooling operations, the pressure was allowed to naturally decrease with the reduction in temperature until a safe venting temperature was reached, which, in this example was about 120° C. (250° F.)

TABLE V

| | Start | End | Temp. Ramp | Pressure | |
|---|---|---|---|---|---|
| Oper- | Temperature | Temperature | Rate ° C./min | MPa | Time |
| ation | ° C. (° F.) | ° C. (° F.) | (° F./min) | (tsi) | (min) |
| Heat | Ambient | 350 (662) | 3 (5.4) | ↑27.6 | As |
| | | | | ↑(2) | Required |
| Hold | 350 (662) | 350 (662) | 0 | 27.6 (2) | 15 |
| Heat | 350 (662) | 650 (1202) | 1 (1.8) | ↑55.2 | ~300 |
| | | | | ↑(4) | |
| Hold | 650 (1202) | 650 (1202) | 0 | 55.2 (4) | 30 |
| Heat | 650 (1202) | 1075 (1967) | 3 (5.4) | ↑203.4 | ~142 |
| | | | | ↑(14.75) | |
| Hold | 1075 (1967) | 1075 (1967) | 0 | 203.4 | 245 |
| | | | | (14.75) | |
| Cool | 1075 (1967) | 650 (1202) | −3 (−5.4) | Pressure | ~142 |
| | | | | allowed | |
| Cool | 650 (1202) | 350 (662) | −1 (−1.8) | to | ~300 |
| Cool | 350 (662) | Safe | −3 (−5.4) | decrease | As |
| | | Venting | | with | Required |
| | | Temperature | | Temp. | |

After the hot-isostatic compaction process was complete, the metal article or billet 42 was removed from the container 84. The billet 42 was then placed in a lathe and machined to produce four (4) disk-shaped articles in the form of a sputter target 44, as described below.

After removal from the container 84, it was noted that the billet 42 had a crack in it near the top. The crack had a dome-shaped geometry and the billet 42 separated at the crack early in the machining process. Subsequent analysis suggested that the crack developed during the initial consolidation process (i.e., during the cold isostatic pressing process). The crack then allowed potassium molybdate to concentrate in the region of the crack during the subsequent hot isostatic pressing process. However, the analysis was not entirely conclusive. Nevertheless, and despite the presence of the crack, the remainder of the billet 42 was substantially uniform in appearance and yielded four high-quality sputter target disks 44. The disks 44 were visually characterized as having a metallic luster and appeared to be homogeneous.

The potassium and trace contents of the billet 42 were measured at various locations by collecting the turnings produced during the various stages of machining. The results of those analyses are presented in Tables VI and VII. More particularly, Table VI lists measured potassium content, in weight percent, as determined by ICP. Interestingly, the potassium assays of the turnings indicate a higher concentration of potassium than was present in the composite powder product 12 used to form the billet 42. It is believed that this discrepancy is due to measurement error of the composite powder product 12, as the potassium levels obtained from the turnings are more consistent with the potassium level that should have been in the composite powder product 12 based on the amount of potassium molybdate provided in the slurry 20. Table VI also includes the theoretical density of the billet 42 based on the potassium assays from the various turnings using the rule of mixtures (ROM) approximation.

TABLE VI

| | Potassium | Theoretical |
|---|---|---|
| Location of Turnings Source | (wt. %) | Density (g/cc) |
| Outer | 2.3 | 8.84 |
| Between Disks 1 and 2 | 2.39 | 8.8 |
| Between Disks 3 and 4 | 2.33 | 8.83 |
| Between Disk 4 and Billet Remnant | 2.27 | 8.86 |

Table VII presents trace amounts of sodium, iron, nickel, chromium, tungsten, and silicon, in units of parts per million (ppm), for the various turnings, as determined by GDMS.

TABLE VII

| Location of | | | | | | |
|---|---|---|---|---|---|---|
| Turnings Source | Na | Fe | Ni | Cr | W | Si |
| Outer | 230 | 16 | 2.2 | 5.6 | 88 | 5 |
| Between Disks 1 and 2 | Not Measured | | | | | |
| Between Disks 3 and 4 | | | | | | |
| Between Disk 4 and Billet Remnant | 300 | 25 | 2.2 | 5.2 | 100 | 12 |

The apparent and theoretical densities, in units of g/cc, of the various disks 44 are presented in Table VIII. The apparent densities of the disks ranged in density from 8.46 to 8.51 g/cc. The apparent densities presented in Table VIII were determined by measuring the dimensions of the machined disks 44 to calculate the disk volume. The measured mass of each machined disk 44 was then divided by its measured volume to arrive at the density. The theoretical densities of the disks 44 was determined based on the potassium analyses of the turnings between disks 1 and 2 and between disks 3 and 4 using the rule of mixtures (ROM) approximation. Thus, the approximate densities of the disks 44 ranged from 96.1 to 96.7% of theoretical, based on the rule of mixtures (ROM). Approximate density with respect to molybdenum (based on the ROM) is also presented in Table VIII.

TABLE VIII

| | Apparent | Theoretical | | |
|---|---|---|---|---|
| | Density | Density | With Respect | With Respect |
| Disk | (g/cc) | (g/cc) | to ROM (%) | to Mo (%) |
| 1 | 8.46 | 8.80 | 96.1 | 82.8 |
| 2 | 8.51 | 8.80 | 96.7 | 83.2 |
| 3 | 8.51 | 8.83 | 96.4 | 83.3 |
| 4 | 8.51 | 8.83 | 96.4 | 83.3 |

Having herein set forth preferred embodiments of the present invention, it is anticipated that suitable modifications can be made thereto which will nonetheless remain within the scope of the invention. The invention shall therefore only be construed in accordance with the following claims:

1. A method for producing a composite metal powder, comprising:
providing a supply of molybdenum metal powder;
providing a supply of a Group IA alkali metal compound;
combining said molybdenum metal powder and said Group IA alkali metal compound with a liquid to form a slurry;
feeding said slurry into a stream of hot gas; and
recovering the composite metal powder, said composite metal powder comprising the Group IA alkali metal compound and molybdenum.

2. The method of claim 1, wherein providing a supply of a Group IA alkali metal compound comprises providing a supply of a potassium compound.

3. The method of claim 2, wherein providing a supply of a potassium compound comprises providing a supply of potassium molybdate powder.

4. The method of claim 1, wherein feeding said slurry into a stream of hot gas comprises atomizing said slurry and contacting said atomized slurry with the stream of hot gas.

5. The method of claim 2, wherein combining said molybdenum metal powder and said potassium compound with a liquid comprises combining said molybdenum metal powder and said potassium compound with water to form a slurry.

6. The method of claim 2, wherein said slurry comprises between about 15% to about 25% by weight liquid.

7. The method of claim 2, further comprising:
providing a supply of a binder material; and
combining said binder material with said molybdenum metal powder, said potassium compound, and said water to form a slurry.

8. The method of claim 7, wherein said potassium compound comprises potassium molybdate and wherein said slurry comprises between about 15% to about 25% by weight liquid, from about 0% to about 2% by weight binder, from about 1% by weight to about 31% by weight potassium molybdate, and from about 52% by weight to about 84% by weight molybdenum metal powder.

9. The method of claim 1, wherein providing a supply of a Group IA alkali metal compound comprises providing a supply of a potassium compound and providing a supply of a sodium compound.

10. The method of claim 9, wherein providing a supply of a potassium compound comprises providing a supply of potassium molybdate and wherein providing a supply of a sodium compound comprises providing a supply of sodium molybdate.

11. A method for producing a dry blend metal powder, comprising:
providing a powder supply of molybdenum metal;
providing a powder supply comprising a Group IA alkali metal;
milling at least one of said powder supply of molybdenum metal and said powder supply comprising a Group IA alkali metal to reduce a particle size of the at least one of said powder supplies; and
combining said powder supply of molybdenum metal powder and said powder supply comprising a Group IA alkali metal to form said dry blend metal powder.

12. A potassium/molybdenum composite metal powder product comprising a substantially homogeneous dispersion of sub-particles comprising potassium and molybdenum sub-particles that are fused together to form individual particles of said composite metal powder.

13. The potassium/molybdenum composite metal powder product of claim 12 having a Scott density in a range of about 1.5 g/cc to about 3 g/cc.

14. The potassium/molybdenum composite metal powder product of claim 12, comprising from about 0.3% by weight to about 11.3% by weight retained potassium.

15. The potassium/molybdenum composite metal powder product of claim 12 wherein said individual particles comprising said composite metal powder product have sizes in a range of about 1 μm to about 150 μm.

16. A method for producing a metal article, comprising:
providing a supply of a potassium/molybdenum composite metal powder;
compacting the potassium/molybdenum composite metal powder under sufficient pressure to form a preformed article;
placing the preformed article in a sealed container;
raising the temperature of the sealed container to a temperature that is lower than an optimal sintering temperature of molybdenum; and
subjecting the sealed container to an isostatic pressure for a time sufficient to increase the density of the article to at least about 90% of theoretical density.

17. The method of claim 16, wherein raising the temperature of the sealed container comprises raising the temperature of the sealed container to a temperature in a range of about 890° C. to about 1250° C.

18. The method of claim 16, wherein subjecting the sealed container to an isostatic pressure comprises subjecting the sealed container to an isostatic pressure in a range of about 102 MPa to about 205 MPa.

19. The method of claim 16, wherein subjecting the sealed container to a hot isostatic pressing process is conducted for a time in a range of about 4 hours to about 8 hours.

20. The method of claim 16, wherein said compacting comprises subjecting the potassium/molybdenum composite metal powder to a uniaxial pressure in a range of about 67 MPa to about 1,103 MPa to form the preformed article.

21. The method of claim 16, wherein said compacting comprises subjecting the potassium/molybdenum composite metal powder to a cold isostatic pressure in a range of about 138 MPa to about 414 MPa to form the preformed article.

22. A metal article produced by the method of claim 16.

23. The metal article of claim 22, wherein said metal article comprises a sputter target.

24. The metal article of claim 22, wherein said potassium is present in an amount of at least about 2% by weight.

25. A method for producing a photovoltaic cell, comprising:
providing a substrate;
depositing a molybdenum metal layer on said substrate;
depositing a potassium/molybdenum metal layer on said molybdenum metal layer by sputtering a target comprising a potassium/molybdenum metal matrix, sputtered material from the target forming said potassium/molybdenum metal layer;
depositing an absorber layer on said potassium/molybdenum metal layer; and
depositing a junction partner layer on said absorber layer.
